(19) United States
(12) Patent Application Publication
(10) Pub. No.: US 2020/0251645 A1
(43) Pub. Date: Aug. 6, 2020

(54) THERMOELECTRIC CONVERSION DEVICE

(71) Applicant: TDK CORPORATION, Tokyo (JP)

(72) Inventor: Makoto SHIBATA, Tokyo (JP)

(73) Assignee: TDK CORPORATION, Tokyo (JP)

(21) Appl. No.: 16/710,013

(22) Filed: Dec. 11, 2019

(30) Foreign Application Priority Data
Feb. 6, 2019 (JP) 2019-020081

(51) Int. Cl. H01L 35/32; H01L 35/22; F01N 5/02

(52) U.S. Cl. CPC H01L 35/32; F01N 5/025; H01L 35/22

(57) ABSTRACT

The thermoelectric conversion device includes thermoelectric conversion elements disposed in a row in a first direction and a second direction that intersect each other in a plane on a first surface side of a base material, hot junction portions thermally connected to ends on hot junction sides of the thermoelectric conversion elements, and cold junction portions thermally connected to ends on cold junction sides of the thermoelectric conversion elements. The hot junction portions and the cold junction portions are alternately disposed in a row in the first direction and the second direction. The base material has thin portions provided corresponding to junction portions that are either the hot junction portions or the cold junction portions and thick portions provided corresponding to the other junction portions. The thick portions that are adjacent in a third direction different from the first and second directions are connected.

### BACKGROUND

The disclosure relates to a thermoelectric conversion device. Priority is claimed on Japanese Patent Application No. 2019-020081, filed Feb. 6, 2019, the content of which is incorporated herein by reference.

For example, exhaust heat from an internal combustion engine or a combustion device disappears without being used. Therefore, the use of such exhaust heat has attracted attention in recent years from the viewpoint of energy saving. In particular, research on thermoelectric conversion devices that enable conversion from heat to electricity has been actively conducted (for example, see the following PCT International Publication No. WO2011/065185).

Specifically, the following PCT International Publication No. WO2011/065185 discloses a thermoelectric conversion module (thermoelectric conversion device) including an insulating substrate, a plurality of thermoelectric conversion material films (thermoelectric conversion elements), which are made of either p-type or n-type thermoelectric conversion materials and are disposed apart from each other on a first surface of the insulating substrate, a first electrode and a second electrode formed apart from each other on each thermoelectric conversion material film, a first heat transfer member disposed on the first surface side of the insulating substrate and provided with a protrusion that is in contact with the first electrode, and a second heat transfer member disposed on the second surface side of the insulating substrate and provided with a protrusion that is in contact with a region corresponding to the second electrode on the second surface of the insulating substrate.

This thermoelectric conversion module has a configuration in which a first electrode is formed along one side of a thermoelectric conversion material film, a second electrode is formed along another side of the thermoelectric conversion material film that is opposite to the one side, the first electrode is connected to a second electrode on a thermoelectric conversion material film adjacent to the one side, and the second electrode is connected to a first electrode on a thermoelectric conversion material film adjacent to the other side.

Incidentally, to improve the thermoelectric conversion characteristics of the thermoelectric conversion device described above, it is important to increase the temperature difference between a hot junction side and a cold junction side of the thermoelectric conversion element. Further, to efficiently use heat from the heat source, it is necessary to concentrate heat transferred from the heat source on the hot junction side of the thermoelectric conversion element.

For example, in the thermoelectric conversion module described in PCT International Publication No. WO2011/065185, since heat is transferred from the hot junction side of the thermoelectric conversion element to the cold junction side through the insulating substrate, there are problems that the temperature difference between the hot junction side and the cold junction side cannot be increased and the output is not improved.

As a countermeasure against this, the present inventors have studied methods of increasing the temperature difference between the hot junction side and the cold junction side and improving the output by providing thin portions or holes in the insulating substrate to curb heat conduction through the insulating substrate.

However, when such thin portions or holes are provided, the mechanical strength of the insulating substrate is lowered and damage or the like easily occurs in the insulating substrate.

### SUMMARY

It is desirable to provide a thermoelectric conversion device that enables further improvement of the output while maintaining the mechanical strength of a base material.

The thermoelectric conversion device including:

a base material having a first surface and a second surface facing each other in a thickness direction,

thermoelectric conversion elements disposed in a row in a first direction and a second direction that intersect each other in a plane on a first surface side of the base material,

hot junction portions thermally connected to ends on hot junction sides of the thermoelectric conversion elements, and

cold junction portions thermally connected to ends on cold junction sides of the thermoelectric conversion elements,

wherein the hot junction portions and the cold junction portions are alternately disposed in a row in the first direction and are alternately disposed in a row in the second direction,

the base material has thin portions or holes provided corresponding to junction portions that are either the hot junction portions or the cold junction portions and thick portions provided corresponding to other junction portions of the hot junction portions and the cold junction portions, and

the thick portions that are adjacent in a third direction different from the first and second directions are connected.

### BRIEF DESCRIPTION OF THE DRAWINGS

FIG. 1 is a perspective view showing an appearance of a thermoelectric conversion device according to an embodiment of the disclosure.

FIG. 2 is a perspective plan view showing a configuration of the thermoelectric conversion device shown in FIG. 1.

FIG. 3 is a cross-sectional view of the thermoelectric conversion device taken along line AA shown in FIG. 2.

FIG. 4 is a cross-sectional view of the thermoelectric conversion device taken along line BB shown in FIG. 2.

FIG. 5 is a cross-sectional view of the thermoelectric conversion device taken along line CC shown in FIG. 2.

FIG. 6 is a perspective plan view showing an enlarged main part of the thermoelectric conversion device shown in FIG. 2.

FIG. 7 is a schematic plan view showing the shape and arrangement of thin portions and thick portions of the thermoelectric conversion device shown in FIG. 2.

FIG. 8 is a schematic plan view showing the shape and arrangement of thin portions and thick portions of a thermoelectric conversion device as a comparative example.

FIG. 9 is a schematic plan view showing the shape and arrangement of thin portions and thick portions of a thermoelectric conversion device as a modification.

FIGS. 10A to 10D are perspective plan views showing shapes of thin portions.

### DETAILED DESCRIPTION

Hereinafter, embodiments of the disclosure will be described in detail with reference to the drawings.

In the drawings used in the following description, to make features easy to understand, portions corresponding to the features are sometimes shown in an enlarged form for the sake of convenience and the dimensional ratios and the like of components are not always the same as the actual ones. Materials and the like exemplified in the following description are also examples, to which the disclosure is not necessarily limited, and can be appropriately modified and implemented without departing from the scope of the disclosure.

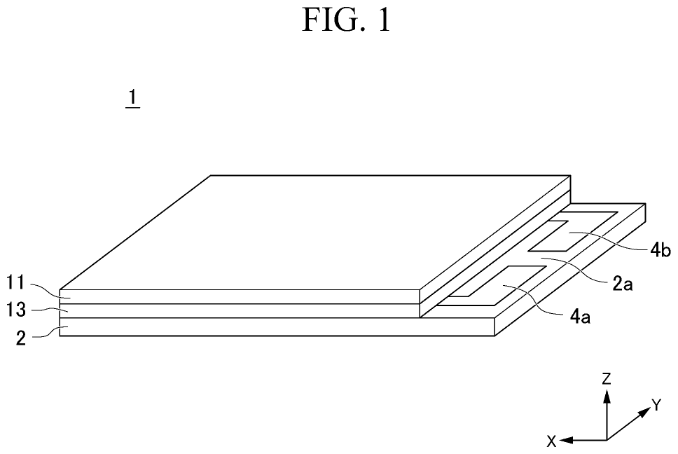

For example, a thermoelectric conversion device 1 shown in FIGS. 1 to 7 will be described as an embodiment of the disclosure.

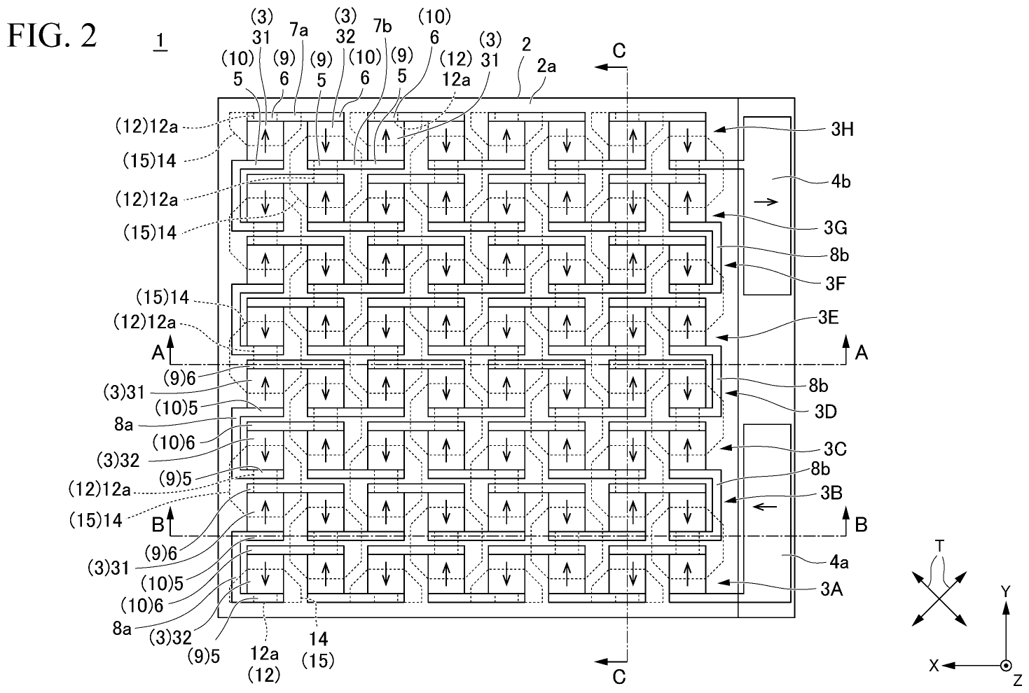

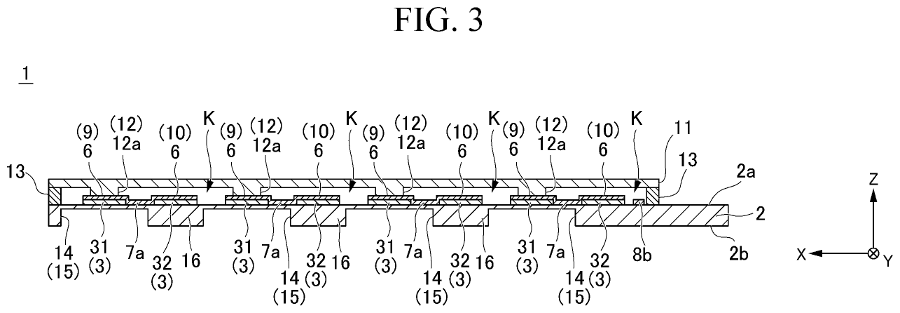

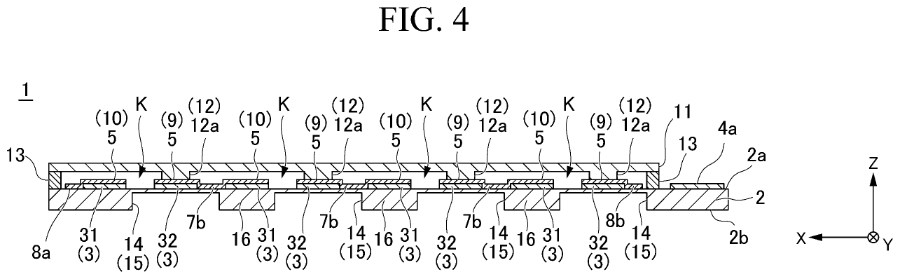

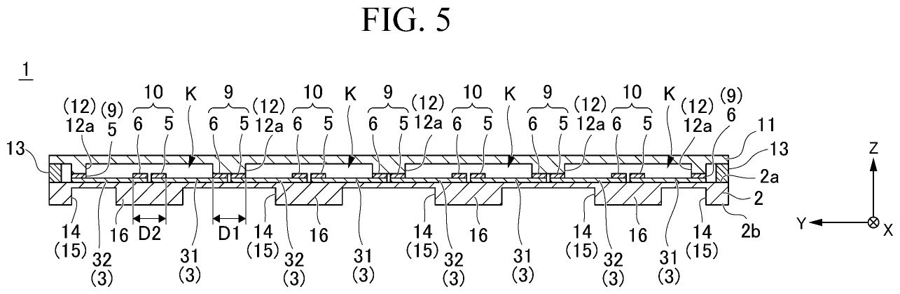

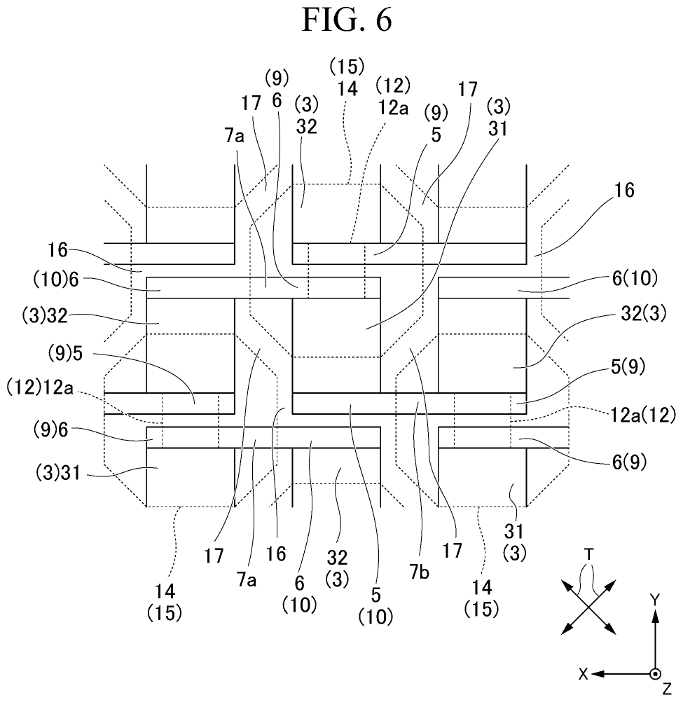

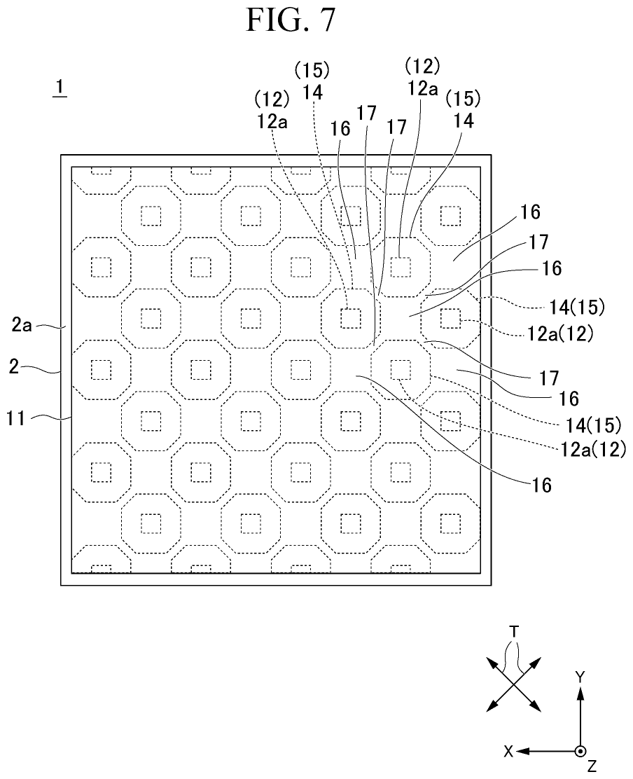

FIG. 1 is a perspective view showing an appearance of the thermoelectric conversion device 1. FIG. 2 is a perspective plan view showing a configuration of the thermoelectric conversion device 1. FIG. 3 is a cross-sectional view of the thermoelectric conversion device 1 taken along line AA shown in FIG. 2. FIG. 4 is a cross-sectional view of the thermoelectric conversion device 1 taken along line BB shown in FIG. 2. FIG. 5 is a cross-sectional view of the thermoelectric conversion device 1 taken along line CC shown in FIG. 2. FIG. 6 is a perspective plan view showing an enlarged main part of the thermoelectric conversion device 1 shown in FIG. 2. FIG. 7 is a schematic plan view showing the shape and arrangement of thin portions 15 and thick portions 16 of the thermoelectric conversion device 1.

In the drawings shown below, an XYZ orthogonal coordinate system is set with that an X-axis direction shown as a first direction X in the plane of a substrate 2 of the thermoelectric conversion device 1, a Y-axis direction shown as a second direction Y in the plane of the substrate 2 of the thermoelectric conversion device 1, and a Z-axis direction shown as a thickness direction Z orthogonal to the plane of the substrate 2 of the thermoelectric conversion device 1.

As shown in FIGS. 1 and 2, the thermoelectric conversion device 1 of the present embodiment has a structure in which a plurality of thermoelectric conversion elements 3 disposed in a row on a surface of the substrate 2 are connected in series between a pair of terminals 4a and 4b.

As shown in FIGS. 2 to 5, the substrate 2 is made of an insulating base material having a first surface (an upper surface in the present embodiment) 2a and a second surface (a lower surface in the present embodiment) 2b that are opposite to each other in the thickness direction Z. For example, a high resistance silicon (Si) substrate having a sheet resistance of 10Ω or more is preferably used as the substrate 2. With the sheet resistance of the substrate 2 of 10Ω or more, it is possible to prevent the occurrence of an electrical short circuit between the plurality of thermoelectric conversion elements 3.

In addition to the high-resistance Si substrate described above, for example, a silicon on insulator (SOI) substrate including an oxide insulating layer therein, a ceramic substrate, or other high-resistance single crystal substrates can be used as the substrate 2. Even a low-resistance substrate having a sheet resistance of 10Ω or less can be used as the substrate 2 with a high-resistance material disposed between the low-resistance substrate and thermoelectric conversion elements 3.

The plurality of thermoelectric conversion elements 3 are disposed in a row in a matrix on the first surface 2a of the substrate 2. Each of the plurality of thermoelectric conversion elements 3 is formed of a thermoelectric conversion film which is either an n-type semiconductor or a p-type semiconductor (an n-type semiconductor in the present embodiment). When the thermoelectric conversion element 3 is an n-type thermoelectric conversion film, for example, a multilayer film including an n-type silicon (Si) film and an n-type silicon-germanium (SiGe) alloy film, each of which is doped with antimony (Sb) at a high concentration (10¹⁸ to 10¹⁹ cm⁻³), can be used as the n-type thermoelectric conversion film. The plurality of thermoelectric conversion elements 3 may be n-type semiconductors having the same configuration or may be n-type semiconductors having different configurations. When the thermoelectric conversion element 3 is an n-type semiconductor, a current flows through the thermoelectric conversion element 3 from a cold junction side to a hot junction side thereof.

On the other hand, when the thermoelectric conversion element 3 is a p-type thermoelectric conversion film, for example, a multilayer film including a p-type silicon (Si) film and a p-type silicon-germanium (SiGe) alloy film, each of which is doped with boron (B) at a high concentration (10¹⁸ to 10¹⁹ cm⁻³), can be used as the p-type thermoelectric conversion film. The plurality of thermoelectric conversion elements 3 may be p-type semiconductors having the same configuration or may be p-type semiconductors having different configurations. When the thermoelectric conversion element 3 is a p-type semiconductor, a current flows through the thermoelectric conversion element 3 from a hot junction side to a cold junction side thereof.

The thermoelectric conversion element 3 is not necessarily limited to the n-type or p-type semiconductor multilayer film described above and may be an n-type or p-type semiconductor single-layer film. An oxide semiconductor can also be used as the semiconductor. For example, a thermoelectric conversion film made of an organic polymer film or a metal film can be used. The thermoelectric conversion element 3 is not limited to the thermoelectric conversion film described above and a bulky thermoelectric conversion element may also be used.

The thermoelectric conversion device 1 of the present embodiment includes a plurality of (eight in the present embodiment) thermoelectric conversion element arrays 3A to 3H, which are disposed in a row in the second direction Y and each of which includes a plurality of (eight in the present embodiment) thermoelectric conversion elements 3 disposed in a row in the first direction X among the first and second directions X and Y intersecting each other (orthogonal to each other in the present embodiment) in the plane of the substrate 2 on the first surface 2a side.

Each of the thermoelectric conversion elements 3 constituting the thermoelectric conversion element arrays 3A to 3H has the same size and is formed in a right-angled quadrilateral shape (a rectangular shape in the present embodiment) in a plan view. The thermoelectric conversion elements 3 are disposed in a row at regular intervals therebetween in the first direction X with the first direction X being a transverse direction of each of the thermoelectric conversion elements 3 and the second direction Y being a longitudinal direction thereof. One thermoelectric conversion element array and another thermoelectric conversion element array which are adjacent in the second direction Y are disposed in a row in parallel to each other with a certain distance therebetween.

The thermoelectric conversion device 1 includes first electrodes 5 provided on first end sides in the second direction Y (−Y sides) of the thermoelectric conversion elements 3 constituting the thermoelectric conversion element arrays 3A to 3H and second electrodes 6 provided on second end sides in the second direction Y (+Y sides) of the thermoelectric conversion elements 3. A first electrode 5 and a second electrode 6 are electrically connected to each thermoelectric conversion element 3.

A metal is preferably used as a material for the first electrode 5 and the second electrode 6 and among metals, in particular, a metal whose electric and thermal conductivity is high and whose shape processing is easy, for example, copper (Cu) or gold (Au), can be preferably used.

The first electrode 5 and the second electrode 6 are disposed on an upper surface of the thermoelectric conversion element 3, respectively, along a side surface on the first end side and a side surface on the second end side of the thermoelectric conversion element 3 that are opposite to each other in the second direction Y. The first electrode 5 and the second electrode 6 may be disposed on the first surface 2a of the substrate 2 and configured such that the first electrode 5 and the second electrode 6 are in contact respectively with the side surface of the first end side and the side surface of the second end side of the thermoelectric conversion element 3 that are opposite to each other in the second direction Y.

Each of the first electrode 5 and the second electrode 6 has the same size and is formed in a right-angled quadrilateral shape (a rectangular shape in the present embodiment) in a plan view over an entire area in the transverse direction (the first direction X) of the thermoelectric conversion element 3. Between one thermoelectric conversion element 3 and another thermoelectric conversion element 3 that are adjacent in the second direction Y, a first electrode 5 (or a second electrode 6) of the one thermoelectric conversion element 3 and a second electrode 6 (or a first electrode 5) of the other thermoelectric conversion element 3 are disposed apart from each other.

The thermoelectric conversion device 1 includes thermoelectric conversion elements 3 in which a current flows from the first electrode 5 side toward the second electrode 6 side (hereinafter indicated as “first thermoelectric conversion elements 31” as necessary) and thermoelectric conversion elements 3 in which a current flows from the second electrode 6 side toward the first electrode 5 side (hereinafter indicated as “second thermoelectric conversion elements 32” as necessary) among the plurality of thermoelectric conversion elements 3.

In FIG. 2, the direction of a current flowing from one terminal 4a toward the other terminal 4b, the directions of currents flowing through the first thermoelectric conversion elements 31, and the directions of currents flowing through the second thermoelectric conversion elements 32 are represented by the directions of arrows.

Each of the plurality of thermoelectric conversion element arrays 3A to 3H has a configuration in which thermoelectric conversion elements 3 in which the directions of currents flowing between the first electrodes 5 and the second electrodes 6 are opposite to each other are alternately disposed in a row in the first direction X. That is, in the thermoelectric conversion element arrays 3A to 3H, first thermoelectric conversion elements 31 and second thermoelectric conversion elements 32 are alternately disposed in a row in the first direction X.

The thermoelectric conversion device 1 also has a configuration in which thermoelectric conversion elements 3 in which the directions of currents flowing between the first electrodes 5 and the second electrodes 6 are opposite to each other are alternately disposed in a row in the second direction Y. That is, in the thermoelectric conversion device 1, first thermoelectric conversion elements 31 and second thermoelectric conversion elements 32 are alternately disposed in a row in the second direction Y.

In the thermoelectric conversion device 1 of the present embodiment, in each of the thermoelectric conversion element arrays 3A, 3C, 3E, and 3G, first thermoelectric conversion elements 31 and second thermoelectric conversion elements 32 are alternately disposed in a row from the first end side toward the second end side in the first direction X. On the other hand, in each of the thermoelectric conversion element arrays 3B, 3D, 3F, and 3H, second thermoelectric conversion elements 32 and first thermoelectric conversion elements 31 are alternately disposed in a row from the first end side to the second end side in the first direction X.

Therefore, in the thermoelectric conversion device 1 of the present embodiment, the first thermoelectric conversion elements 31 and the second thermoelectric conversion elements 32 are disposed in a row in a staggered manner in the first direction X and the second direction Y in the plane on the first surface 2a side of the substrate 2.

The pair of terminals 4a and 4b are disposed on the first surface 2a of the substrate 2. The same material as that exemplified above for the first electrode 5 and the second electrode 6 can be used as a material of the pair of terminals 4a and 4b.

Of the pair of terminals 4a and 4b, the one terminal 4a is electrically connected to a first electrode 5 of a thermoelectric conversion element 3 (a first thermoelectric conversion element 31) that is located furthest to the first end side (−X side) in the first direction X among thermoelectric conversion elements 3 constituting the thermoelectric conversion element array 3A that is located furthest to the first end side (−Y side) in the second direction Y. That is, the one terminal 4a is formed in a right-angled quadrilateral shape (a rectangular shape in the present embodiment) in a plan view at a position protruding outward (to the −X side) from the first electrode 5 while being continuous with the first electrode 5 in a longitudinal direction of the first electrode 5 (the first direction X).

On the other hand, the other terminal 4b is electrically connected to a first electrode 5 of a thermoelectric conversion element 3 (a second thermoelectric conversion element 32) that is located furthest to the first end side (−X side) in the first direction X among thermoelectric conversion elements 3 constituting the thermoelectric conversion element array 3H that is located furthest to the second end side (+Y side) in the second direction Y. That is, the other terminal 4b is formed in a right-angled quadrilateral shape (a rectangular shape in the present embodiment) in a plan view at a position protruding outward (to the −X side) from the first electrode 5 while being continuous with the first electrode 5 in a longitudinal direction of the first electrode 5 (the first direction X).

The thermoelectric conversion device 1 of the present embodiment includes a plurality of first wirings 7a and 7b that connect a plurality of thermoelectric conversion elements 3, which constitute each of the thermoelectric conversion element arrays 3A to 3H, in series and a plurality of second wirings 8a and 8b that connect a plurality of thermoelectric conversion element arrays 3A to 3H in series such that a plurality of thermoelectric conversion elements 3, which constitute one of each pair of thermoelectric conversion element arrays that are adjacent in the second direction Y among the thermoelectric conversion element arrays 3A to 3H, and a plurality of thermoelectric conversion elements 3, which constitute the other of the pair of thermoelectric conversion element arrays, are connected in series.

The plurality of first wirings 7a and 7b and the plurality of second wirings 8a and 8b are disposed on the first surface 2a of the substrate 2 and are each formed continuously with a first electrode 5 or a second electrode 6 electrically connected thereto. Therefore, the same material as that exemplified above for the first electrode 5 and the second electrode 6 can be used as a material of the first wirings 7a and 7b and the second wirings 8a and 8b.

Each of the first wirings 7a and 7b is disposed between one thermoelectric conversion element and another thermoelectric conversion element that are adjacent in the first direction X among a plurality of thermoelectric conversion elements 3 constituting each of the thermoelectric conversion element arrays 3A to 3H. Each of the first wirings 7a and 7b electrically connects first electrodes 5 or second electrodes 6 of the one thermoelectric conversion element and the other thermoelectric conversion element 3.

Specifically, a second electrode (hereinafter referred to as “one second electrode”) 6 of a thermoelectric conversion element 3 positioned 2m−1th (where m represents a natural number) from the first end side (−X side) in the first direction X among thermoelectric conversion elements 3 constituting each of the thermoelectric conversion element arrays 3A to 3H shown in FIG. 2 and a second electrode (hereinafter referred to as “another second electrode”) 6 of a thermoelectric conversion element 3 positioned 2mth from the first end side (−X side) in the first direction X are electrically connected via a first wiring 7a having a linear shape that is aligned with these second electrodes 6 along the same straight line (where m=1 to 4 in the present embodiment).

The first wiring 7a is formed in a straight line shape along the same straight line as the one second electrode 6 and the other second electrode 6 while being continuous with the other end in a longitudinal direction (the first direction X) of the one second electrode 6 and the one end in the longitudinal direction (the first direction X) of the other second electrode 6, thereby wiring the one second electrode 6 and the other second electrode 6 together. That is, the one second electrode 6, the other second electrode 6, and the first wiring 7a are formed in a line.

In addition, a first electrode (hereinafter referred to as “one first electrode”) 5 of a thermoelectric conversion element 3 positioned 2mth from the first end side (−X side) in the first direction X among thermoelectric conversion elements 3 constituting each of the thermoelectric conversion element arrays 3A to 3H and a first electrode (hereinafter referred to as “another first electrode”) 5 of a thermoelectric conversion element 3 positioned 2m+1th from the first end side (−X side) in the first direction X are electrically connected via a first wiring 7b having a linear shape that is aligned with these first electrodes 5 along the same straight line (where m=1 to 3 in the present embodiment).

The first wiring 7b is formed in a straight line shape along the same straight line as the one first electrode 5 and the other first electrode 5 while being continuous with the other end in a longitudinal direction (the first direction X) of the one first electrode 5 and the one end in the longitudinal direction (the first direction X) of the other first electrode 5, thereby wiring the one first electrode 5 and the other first electrode 5 together. That is, the one first electrode 5, the other first electrode 5, and the first wiring 7b are formed in a line.

The second wirings 8a and 8b are disposed outside (on the −X side or the +X side of) thermoelectric conversion elements 3 that are located furthest to the first end side or furthest to the second end side in the first direction X in one thermoelectric conversion element array and another thermoelectric conversion element array which are adjacent in the second direction Y among the plurality of thermoelectric conversion element arrays 3A to 3H. Each of the second wirings 8a and 8b electrically connects first electrodes 5 or second electrodes 6 of the thermoelectric conversion elements 3 that are located furthest to the first end side or furthest to the second end side in the first direction X in the one thermoelectric conversion element array and the other thermoelectric conversion element array.

Specifically, first electrodes 5 of thermoelectric conversion elements 3 located furthest to the second end side (+X side) in the first direction X of the thermoelectric conversion element arrays 3A, 3C, 3E, and 3G that are positioned 2n−1th (where n is a natural number) from the first end side (−Y side) in the second direction Y among the plurality of thermoelectric conversion element arrays 3A to 3H shown in FIG. 2 and first electrodes 5 of thermoelectric conversion elements 3 located furthest to the second end side (+X side) in the first direction X of the thermoelectric conversion element arrays 3B, 3D, 3F, and 3H that are positioned 2nth from the first end side (−Y side) in the second direction Y are electrically connected via bent second wirings 8a (where n=1 to 4 in the present embodiment).

The second wirings 8a are bent at positions protruding outward (to the +X side) from those first electrodes 5 while being continuous with other ends in the longitudinal direction (the first direction X) of the first electrodes 5 and are formed in a straight line shape along a direction (the second direction Y) orthogonal to the first direction X between those first electrodes 5, thereby wiring the first electrodes 5 together.

In addition, first electrodes 5 of thermoelectric conversion elements 3 located furthest to the first end side (−X side) in the first direction X of the thermoelectric conversion element arrays 3B, 3D, and 3F that are positioned 2nth from the first end side (−Y side) in the second direction Y among the plurality of thermoelectric conversion element arrays 3A to 3H and first electrodes 5 of thermoelectric conversion elements 3 located furthest to the first end side (−X side) in the first direction X of the thermoelectric conversion element arrays 3C, 3E, and 3G that are positioned 2n+1th from the first end side (−Y side) in the second direction Y are electrically connected via bent second wirings 8b (where n=1 to 3 in the present embodiment).

The second wirings 8b are bent at positions protruding outward (to the −X side) from those first electrodes 5 while being continuous with one ends in the longitudinal direction (the first direction X) of the first electrodes 5 and are formed in a straight line shape along a direction (the second direction Y) orthogonal to the first direction X between those first electrodes 5, thereby wiring the first electrodes 5 together.

Thereby, in the thermoelectric conversion device 1 of the present embodiment, a plurality of thermoelectric conversion elements 3 constituting each of the thermoelectric conversion element arrays 3A to 3H are connected in series via the plurality of first wirings 7a and 7b. In addition, the plurality of thermoelectric conversion element arrays 3A to 3H are connected in series via the plurality of second wirings 8a and 8b such that a plurality of thermoelectric conversion elements 3 constituting one of each pair of thermoelectric conversion element arrays that are adjacent in the second direction Y among the plurality of thermoelectric conversion element arrays 3A to 3H and a plurality of thermoelectric conversion elements 3 constituting the other thermoelectric conversion element array are connected in series.

As shown in FIGS. 2 to 5, the thermoelectric conversion device 1 has a first electrode 5 or a second electrode 6 located at the hot junction side (hereinafter, collectively referred to as a “hot junction side electrode 9”) and a second electrode 6 or a first electrode 5 located at the cold junction side (hereinafter, collectively referred to as a “cold junction side electrode 10”) at each of the thermoelectric conversion elements 3 constituting the thermoelectric conversion element arrays 3A to 3H.

A hot junction side electrode 9 is constituted by a second electrode 6 of a first thermoelectric conversion element 31 and a first electrode 5 of a second thermoelectric conversion element 32. On the other hand, a cold junction side electrode 10 is constituted by a first electrode 5 of a first thermoelectric conversion element 31 and a second electrode 6 of a second thermoelectric conversion element 32. Therefore, the hot junction side electrodes 9 and the cold junction side electrodes 10 are alternately disposed in a row in the first direction X and are alternately disposed in a row in the second direction Y. That is, the hot junction side electrodes 9 and the cold junction side electrodes 10 are disposed in a row in a staggered manner in the first direction X and the second direction Y.

A hot junction side electrode 9 is constituted by a first electrode 5 and a second electrode 6 that are adjacent in the second direction Y. Further, a cold junction side electrode 10 is constituted by a first electrode 5 and a second electrode 6 that are adjacent in the second direction Y.

However, each of the first electrode 5 of the second thermoelectric conversion element 32 located furthest to the end side (−Y side) in the second direction Y and the second electrode 6 of the first thermoelectric conversion element 31 located furthest to the second end side (+Y side) in the second direction Y alone constitutes a hot junction side electrode 9.

Further, each of the first electrode 5 of the first thermoelectric conversion element 31 located furthest to the end side (−Y side) in the second direction Y and the second electrode 6 of the second thermoelectric conversion element 32 located furthest to the second end side (+Y side) in the second direction Y alone constitutes a cold junction side electrode 10.

The thermoelectric conversion device 1 of the present embodiment includes a heat transfer plate 11 disposed on the first surface 2a side of the substrate 2 as a heat transfer member on the high temperature (heating) side. The heat transfer plate 11 is disposed with a space between it and the thermoelectric conversion element 3. The heat transfer plate 11 is made of a material having a higher thermal conductivity than air, preferably a material having a higher thermal conductivity than the substrate 2. A metal is preferably used as a material for such a heat transfer plate 11 and among metals, in particular, a metal whose thermal conductivity is high and whose shape processing is easy, for example, aluminum (Al) or copper (Cu), can be preferably used. The heat transfer plate 11 may also be constituted by a plurality of heat transfer members.

The heat transfer plate 11 is thermally connected to the hot junction side electrodes 9 via a heat transfer portion 12. The heat transfer portion 12 has protrusions 12a, each protruding from either one of a surface of the heat transfer plate 11 and a surface of a hot junction side electrode 9 that face each other.

In the present embodiment, the heat transfer portion 12 is constituted by protrusions 12a protruding from the heat transfer plate 11 side. Since the protrusions 12a are formed integrally with the heat transfer plate 11, the same material as that exemplified above for the heat transfer plate 11 may be used as a material of the protrusions 12a (the heat transfer portion 12).

The heat transfer portion 12 of the present embodiment has a plurality of protrusions 12a that protrude toward the substrate 2 side (−Z side) from positions facing the hot junction side electrodes 9 of the heat transfer plate 11. Each protrusion 12a has a right-angled quadrilateral shape (a rectangular shape in the present embodiment) in a plan view and protrudes in a range D1 that overlaps a first electrode 5 and a second electrode 6 constituting a corresponding hot junction side electrode 9 when viewed in the thickness direction Z.

A tip of each protrusion 12a is thermally connected to a corresponding hot junction side electrode 9 in a state of being electrically insulated from the corresponding hot junction side electrode 9, for example, through an insulating connecting material (not shown). The connecting material is made of an insulating material having a higher thermal conductivity than air. For example, a UV curable resin, a silicone resin, or a heat conductive grease (for example, a silicone grease or a non-silicone grease containing a metal oxide) can be used as a material of such a connecting material.

The heat transfer portion 12 may be directly connected to the hot junction electrode 9 without through the insulating connecting material described above when the heat transfer portion 12 is electrically insulated from the hot junction side electrode 9 by an insulating layer or the like provided at the tip of the protrusion 12a described above or when the electrical insulation between the tip of the protrusion 12a and the hot junction side electrode 9 is not problematic.

The heat transfer portion 12 is not limited to the above case where it is constituted by protrusions 12a protruding from the heat transfer plate 11 side, and can also be constituted by protrusions 12a, each protruding from the hot junction side electrode 9 side. In this case, since each protrusion 12a is formed integrally with a hot junction side electrode 9 (a first electrode 5 and a second electrode 6), the same material as that exemplified above for the first electrode 5 and the second electrode 6 can be used as a material of the protrusion 12a (the heat transfer portion 12).

Another heat transfer member (including the connecting material described above) that thermally connects the heat transfer plate 11 and the hot junction side electrode 9 can also be provided as the heat transfer portion 12. For example, by making the thickness of the hot junction side electrode 9 greater than the thickness of the cold junction side electrode 10, it is possible to provide a configuration in which the heat transfer plate 11 and the hot junction side electrode 9 are thermally connected through the connecting material provided as the heat transfer portion 12 without through the protrusion 12a described above.

Moreover, in the thermoelectric conversion device 1 of the present embodiment, a space K is provided between the first surface 2a side of the substrate 2 and the heat transfer plate 11 by connecting the heat transfer plate 11 and the hot junction side electrode 9 described above via the heat transfer portion 12 (the protrusion 12a).

In the thermoelectric conversion device 1 of the present embodiment, it is also possible to fill the space K described above with a heat insulating material made of a material having a lower thermal conductivity than the heat transfer portion 12. That is, the heat transfer portion 12 forms a portion giving a relatively higher thermal conductivity between the heat transfer plate 11 and the hot junction side electrode 9 than the surroundings (the space K or the heat insulating material).

In the thermoelectric conversion device 1 of the present embodiment, the substrate 2 and the heat transfer plate 11 are sealed together outside the periphery of the plurality of thermoelectric conversion elements 3 via a sealing material 13 as shown in FIGS. 1 and 3 to 5. The sealing material 13 is made of, for example, a high-temperature adhesive such as a silicone-based adhesive and seals the substrate 2 and the heat transfer plate 11 together around the periphery thereof.

A depressurized space K may be provided between the substrate 2 and the heat transfer plate 11 sealed together by the sealing material 13. The depressurized space K can be formed using a method in which the space between the substrate 2 and the heat transfer plate 11 is sealed with the sealing material 13 in a depressurized atmosphere, a method in which a hole is provided in a part of the sealing material 13 and the hole is sealed after the space K is depressurized through the hole, or the like.

In the thermoelectric conversion device 1 of the present embodiment, the substrate 2 has a configuration in which the thickness of at least a portion of the substrate 2 facing the cold junction side electrode 10 is greater than the thickness of at least a portion thereof facing the hot junction side electrode 9.

Specifically, while the first surface 2a of the substrate 2 is a flat surface, a plurality of recesses 14 are disposed in a row in the first direction X and the second direction Y on the second surface 2b of the substrate 2. Each of the plurality of recesses 14 has a substantially octagonal shape in a plan view and includes a range D1 that overlaps a first electrode 5 and a second electrode 6 constituting a corresponding hot junction side electrode 9 when viewed in the thickness direction Z, and is recessed at a certain depth.

On the other hand, a portion other than the recess 14 includes a range D2 that overlaps a first electrode 5 and a second electrode 6 constituting a corresponding cold junction side electrode 10 when viewed in the thickness direction Z, and protrudes at a certain height from the bottom surface of the recess 14.

Thereby, the substrate 2 has thin portions 15 in parts in which the recesses 14 are provided and thick portions 16 thicker than the thin portions 15 between the adjacent thin portions 15.

Each thin portion 15 is provided corresponding to a hot junction portion that is thermally connected to an end on the hot junction side of each thermoelectric conversion element 3 (a hot junction side electrode 9 in the present embodiment). Specifically, this hot junction portion is constituted by a portion of the protrusion 12a of the heat transfer portion 12 that overlaps a first electrode 5 and a second electrode 6 constituting the hot junction side electrode 9 when viewed in the thickness direction Z.

The thin portion 15 is provided surrounding the hot junction portion in a plan view. That is, the thin portion 15 has a substantially octagonal shape in a plan view and is provided such that the hot junction portion is located at a center portion of the thin portion 15.

In the thermoelectric conversion device 1 of the present embodiment, as shown in FIGS. 6 and 7, thin portions 15 that are adjacent in third directions T different from the first direction X and the second direction Y (two directions that are inclined to opposite sides with respect to the first direction X and the second direction Y in the present embodiment) are provided such that the thin portions 15 overlap each other when viewed in the first direction X and also overlap each other when viewed in the second direction Y.

In the plane of the substrate 2, the sum of the areas of the plurality of thin portions 15 (hereinafter referred to as a “total area of the thin portions 15”) is greater than the sum of the areas of portions other than the thin portions 15 (hereinafter referred to as a “total area other than the thin portions 15”).

Each thick portion 16 is provided corresponding to a cold junction portion that is thermally connected to an end on the cold junction side of each thermoelectric conversion element 3 (a cold junction side electrode 10 in the present embodiment). Specifically, this cold junction portion is constituted by a portion of the thick portion 16 of the substrate 2 that overlaps a first electrode 5 and a second electrode 6 constituting the cold junction side electrode 10 when viewed in the thickness direction Z.

Therefore, the hot junction portions and the cold junction portions are alternately disposed in a row in the first direction X and are alternately disposed in a row in the second direction Y. That is, the hot junction portions and the cold junction portions are alternately disposed in a row in the first direction X and the second direction Y.

The substrate 2 has connecting portions 17 that connect thick portions 16 adjacent in the third directions T. The connecting portions 17 have a thickness greater than that of the thin portions 15 (the same thickness as that of the thick portions 16 in the present embodiment) and are provided extending in the third directions T between thin portions 15 adjacent in the third directions T. That is, the thickness of the connecting portions 17 is greater than the thickness of the thin portions 15.

In the present embodiment, the thick portions 16 and the connecting portions 17 are provided flush with each other in the third directions T since the thick portions 16 and the connecting portions 17 have the same thickness. Therefore, the connecting portions 17 are portions of the substrate 2 that extend in the third directions T between the thin portions 15 adjacent in the third directions T described above although the boundaries between the thick portions 16 and the connecting portions 17 cannot be clearly distinguished.

In the thermoelectric conversion device 1 having the above configuration, the heat transfer plate 11 is disposed on the high temperature (heating) side and the second surface 2b of the substrate 2 is disposed on the low temperature (heat radiation/cooling) side. Thereby, the hot junction side electrode 9 side of each thermoelectric conversion element 3 becomes relatively high in temperature due to heat transferred from the heat transfer plate 11 to the hot junction side electrode 9 through the protrusion 12a (the heat transfer portion 12). On the other hand, since the heat transferred to each thermoelectric conversion element 3 is radiated to the outside from the cold junction side electrode 10 through the thick portion 16 of the substrate 2, the cold junction side electrode 10 side of each thermoelectric conversion element 3 becomes relatively low in temperature. This produces a temperature difference between the hot junction side electrode 9 and the cold junction side electrode 10 of each thermoelectric conversion element 3.

This causes movement of electric charges (carriers) between the first electrode 5 and the second electrode 6 of each thermoelectric conversion element 3. That is, an electromotive force (voltage) due to the Seebeck effect is generated between the first electrode 5 and the second electrode 6 of each thermoelectric conversion element 3 and current flows in each thermoelectric conversion element 3 from the cold junction side electrode 10 toward the hot junction side electrode 9.

Although the electromotive force (voltage) generated in one thermoelectric conversion element 3 is small, a plurality of thermoelectric conversion elements 3 are connected in series between the one terminal 4a and the other terminal 4b. Therefore, a relatively high voltage can be taken out from between the one terminal 4a and the other terminal 4b as a total electromotive force. Further, a current can flow from the one terminal 4a side toward the other terminal 4b side.

The thermoelectric conversion device 1 of the present embodiment has a configuration in which the thick portions 16 adjacent in the third directions T described above are connected via the connecting portions 17. Thereby, the mechanical strength of the substrate 2 can be maintained even when the proportion of the thin portions 15 in the plane of the substrate 2 has increased compared to that of the thick portions 16. The thermoelectric conversion device 1 of the present embodiment has a configuration in which the thick portions 16 adjacent in the third directions T described above are physically connected.

Moreover, in the thermoelectric conversion device 1 of the present embodiment, the proportion of the thin portions 15 in the plane of the substrate 2 increases compared to that of the thick portions 16, whereby heat transferred to the hot junction side electrode 9 side from the heat transfer plate 11 via the heat transfer portion 12 is hardly transferred to the cold junction side electrode 10 side via the substrate 2. This can improve the output of each thermoelectric conversion element 3.

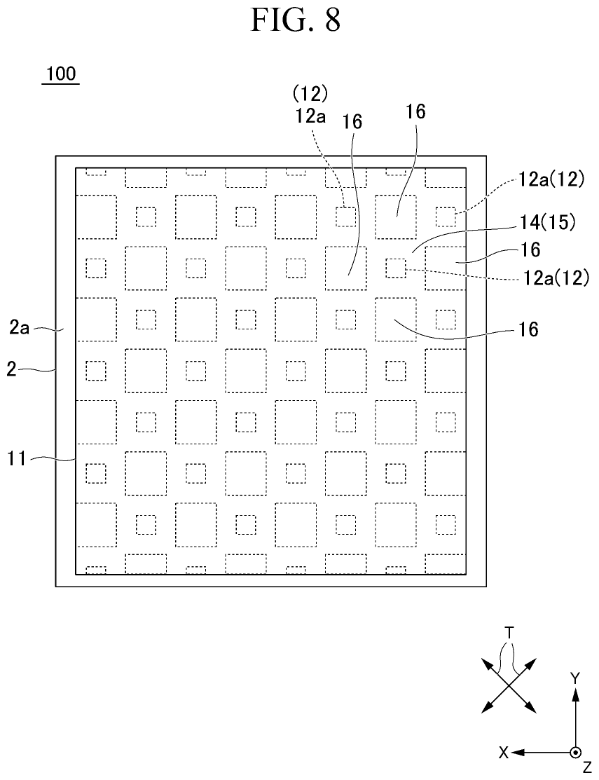

Here, a thermoelectric conversion device 100 as a comparative example will be described as shown in FIG. 8.

FIG. 8 is a schematic plan view showing the shape and arrangement of thin portions 15 and thick portions 16 of the thermoelectric conversion device 100 as a comparative example. In FIG. 8, the same reference signs are assigned to portions equivalent to those of the thermoelectric conversion device 1 described above and the description thereof will be omitted.

As shown in FIG. 8, the thermoelectric conversion device 100 as a comparative example has a configuration in which the proportion of the thin portions 15 increases compared to that of the thermoelectric conversion device 1 shown in FIG. 7, such that the thin portions 15 divide thick portions 16 adjacent in the third directions from each other. In the case of this configuration, the mechanical strength of the substrate 2 is lowered.

On the other hand, in the thermoelectric conversion device 1 of the present embodiment, it is possible to further improve the output while maintaining the mechanical strength of the substrate 2.

The present invention is not necessarily limited to the above embodiment and various modifications can be made without departing from the spirit of the disclosure.

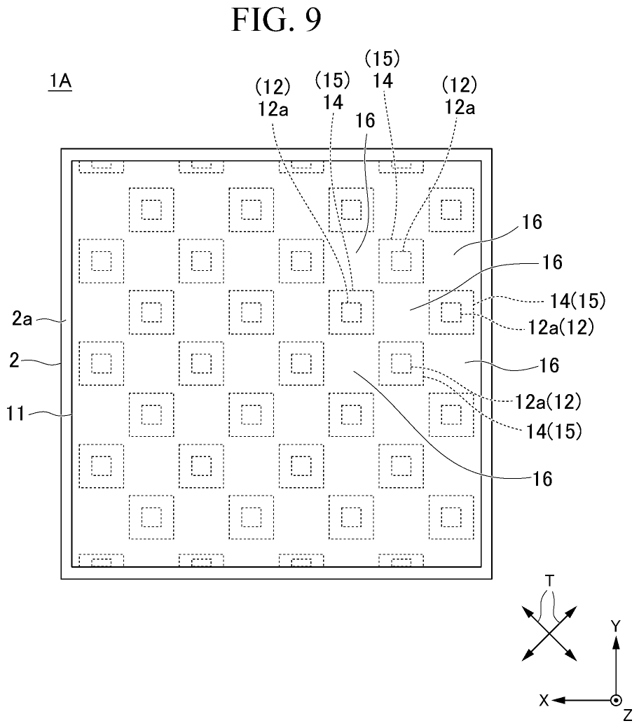

For example, the disclosure may be configured as a thermoelectric conversion device 1A shown in FIG. 9. FIG. 9 is a schematic plan view showing the shape and arrangement of thin portions 15 and thick portions 16 of the thermoelectric conversion device 1A as a modification.

Specifically, as shown in FIG. 9, the thermoelectric conversion device 1A has a configuration in which thick portions 16 adjacent in the third directions T are directly connected without through the connecting portions 17 described above. Moreover, thin portions 15 have a substantially quadrilateral shape (a rectangular shape) in a plan view.

In the case of this configuration, the mechanical strength of the substrate 2 can be maintained although the proportion of the thin portions 15 is reduced compared to that of the thermoelectric conversion device 1.

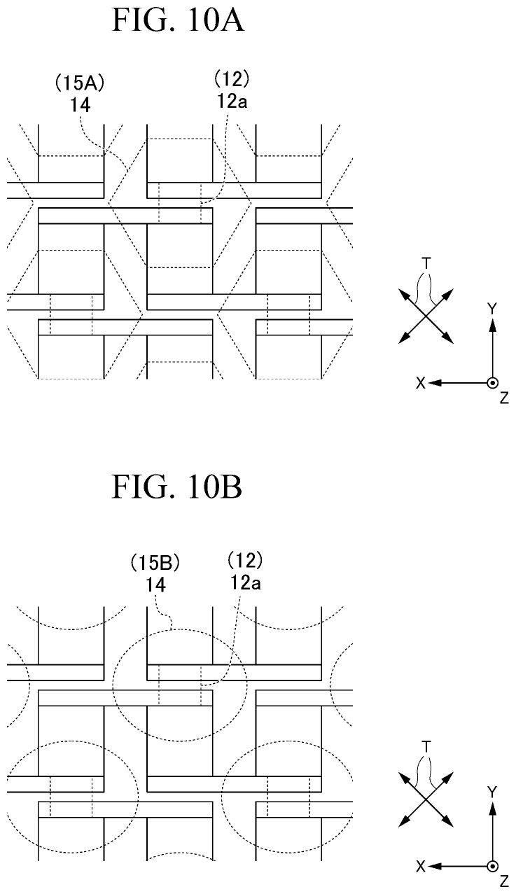

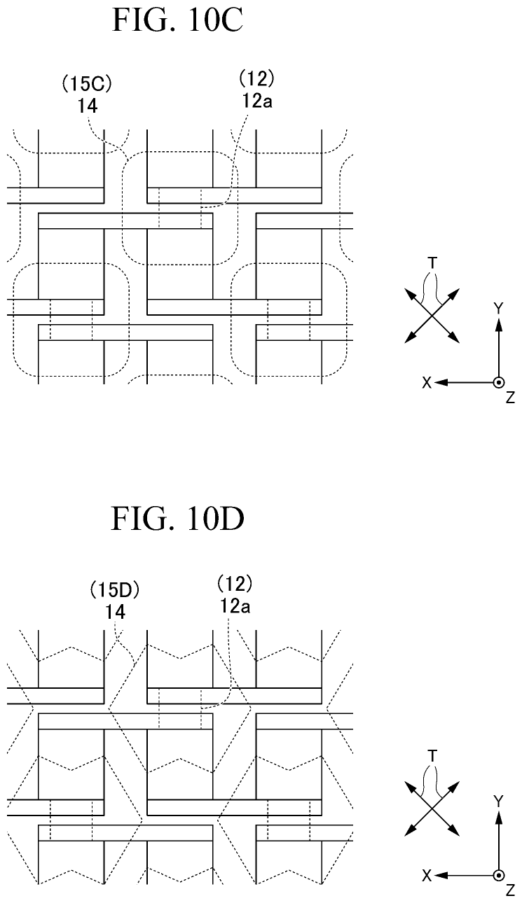

Further, the thin portions 15 described above are not limited to those described above having an octagonal or a quadrilateral shape (a rectangular shape) in a plan view and the shape thereof can be changed as appropriate. For example, the shapes of thin portions 15A to 15D as shown in FIGS. 10A to 10D can be adopted. FIGS. 10A to 10D are perspective plan views showing the shapes of the thin portions 15A to 15D.

The thin portions may have a substantially hexagonal shape in a plan view among such shapes, like the thin portions 15A shown in FIG. 10A. On the other hand, the thin portions may have a substantially circular shape (including an elliptical shape, an oval shape, or the like) in a plan view, like the thin portions 15B shown in FIG. 10B. On the other hand, the thin portions may have a substantially quadrilateral shape with rounded corners in a plan view, like the thin portions 15C shown in FIG. 10C. On the other hand, the thin portions may have an octagonal shape different from those described above in a plan view such that thick portions 16 along two sides of each octagon that are opposite to each other in the second direction Y protrude toward the heat transfer portion 12 side, like the thin portions 15D shown in FIG. 10D.

The thermoelectric conversion devices 1 and 1A may also have a configuration in which holes that penetrate the substrate 2 in the thickness direction Z are formed instead of the thin portions 15 (the recesses 14) described above. The holes may basically have the same configuration as the thin portions 15 (the recesses 14) except that they penetrate the substrate 2 in the thickness direction Z.

In this case, thick portions 16 that are adjacent in the third direction T are also connected similar to the thermoelectric conversion devices 1 and 1A. Thus, even when the proportion of the thin portions 15 in the plane of the substrate 2 is increased compared to that of the thick portions 16, the output can be further improved while maintaining the mechanical strength of the substrate 2.

The thermoelectric conversion devices 1 and 1A have been exemplified with reference to the case where the heat transfer plate 11 is disposed on the high temperature (heat source) side and the substrate 2 is disposed on the low temperature (heat radiation/cooling) side. In this case, the thin portion 15 corresponding to the hot junction portion (one junction portion) and the thick portion 16 corresponding to the cold junction portion (the other junction portion) described above are provided.

On the other hand, in the thermoelectric conversion devices 1 and 1A, the substrate 2 may be disposed on the high temperature (heat source) side and the heat transfer plate 7 may be disposed on the low temperature (heat radiation/cooling) side, such that heat from a heat source is transferred from the substrate 2 side. In this case, the thin portion 15 corresponding to the cold junction portion (one junction portion) and the thick portion 16 corresponding to the hot junction portion (the other junction portion) described above are provided.

The thermoelectric conversion devices 1 and 1A are also exemplary examples for the case where the thermoelectric conversion elements 3 made of n-type semiconductors described above are used. On the contrary, when thermoelectric conversion elements 3 made of p-type semiconductors are used, the directions of currents (arrow directions) flowing through the plurality of thermoelectric conversion elements 3 between the pair of terminals 4a and 4b are reversed.

According to the disclosure, it is possible to provide a thermoelectric conversion device that enables further improvement of the output while maintaining the mechanical strength of the base material as described above. While preferred embodiments of the disclosure have been described and shown above, it should be understood that these are exemplary of the disclosure and are not to be considered as limiting. Additions, omissions, substitutions, and other modifications can be made without departing from the spirit or scope of the disclosure. Accordingly, the invention is not to be considered as being limited by the foregoing description, and is only limited by the scope of the appended claims.

What is claimed is:

1. A thermoelectric conversion device comprising:
a base material having a first surface and a second surface facing each other in a thickness direction;
thermoelectric conversion elements disposed in a row in a first direction and a second direction that intersect each other in a plane on a first surface side of the base material;
hot junction portions thermally connected to ends on hot junction sides of the thermoelectric conversion elements; and
cold junction portions thermally connected to ends on cold junction sides of the thermoelectric conversion elements,
wherein the hot junction portions and the cold junction portions are alternately disposed in a row in the first direction and are alternately disposed in a row in the second direction,
the base material has thin portions or holes provided corresponding to junction portions that are either the hot junction portions or the cold junction portions and thick portions provided corresponding to other junction portions of the hot junction portions and the cold junction portions, and
the thick portions that are adjacent in a third direction different from the first and second directions are connected.

2. The thermoelectric conversion device according to claim 1, wherein the base material has connecting portions which connect the thick portions adjacent in the third direction and have a thickness greater than that of the thin portions or the holes.

3. The thermoelectric conversion device according to claim 2, wherein the connecting portions are provided extending in the third direction.

4. The thermoelectric conversion device according to claim 1, wherein the thin portions or the holes are provided such that the thin portions or the holes that are adjacent in the third direction overlap each other when viewed in the first direction and overlap each other when viewed in the second direction.

5. The thermoelectric conversion device according to claim 2, wherein the thin portions or the holes are provided such that the thin portions or the holes that are adjacent in the third direction overlap each other when viewed in the first direction and overlap each other when viewed in the second direction.

6. The thermoelectric conversion device according to claim 3, wherein the thin portions or the holes are provided such that the thin portions or the holes that are adjacent in the third direction overlap each other when viewed in the first direction and overlap each other when viewed in the second direction.

7. The thermoelectric conversion device according to claim 1, wherein a total area of the thin portions or the holes is larger than a total area other than the thin portions or the holes in a plane of the base material.

8. The thermoelectric conversion device according to claim 2, wherein a total area of the thin portions or the holes is larger than a total area other than the thin portions or the holes in a plane of the base material.

9. The thermoelectric conversion device according to claim 3, wherein a total area of the thin portions or the holes is larger than a total area other than the thin portions or the holes in a plane of the base material.

10. The thermoelectric conversion device according to claim 4, wherein a total area of the thin portions or the holes is larger than a total area other than the thin portions or the holes in a plane of the base material.

11. The thermoelectric conversion device according to claim 5, wherein a total area of the thin portions or the holes is larger than a total area other than the thin portions or the holes in a plane of the base material.

12. The thermoelectric conversion device according to claim 6, wherein a total area of the thin portions or the holes is larger than a total area other than the thin portions or the holes in a plane of the base material.

13. The thermoelectric conversion device according to claim 1, wherein the thin portions or the holes are octagonal in a plan view.

14. The thermoelectric conversion device according to claim 2, wherein the thin portions or the holes are octagonal in a plan view.

15. The thermoelectric conversion device according to claim 3, wherein the thin portions or the holes are octagonal in a plan view.

16. The thermoelectric conversion device according to claim 4, wherein the thin portions or the holes are octagonal in a plan view.

17. The thermoelectric conversion device according to claim 5, wherein the thin portions or the holes are octagonal in a plan view.

18. The thermoelectric conversion device according to claim 6, wherein the thin portions or the holes are octagonal in a plan view.

19. The thermoelectric conversion device according to claim 7, wherein the thin portions or the holes are octagonal in a plan view.
